(19) United States
(12) Patent Application Publication
(10) Pub. No.: US 2013/0285762 A1
(43) Pub. Date: Oct. 31, 2013

(54) VARIABLE CAPACITOR MODULE

(71) Applicant: SAMSUNG ELECTRO-MECHANICS CO., LTD., Suwon (KR)

(72) Inventor: Sang Wook PARK, Suwon (KR)

(73) Assignee: Samsung Electro-Mechanics Co., Ltd., Suwon (KR)

(21) Appl. No.: 13/800,380

(22) Filed: Mar. 13, 2013

(30) Foreign Application Priority Data
Apr. 27, 2012 (KR) 10-2012-0044769

(51) Int. Cl. H03H 7/38

(52) U.S. Cl. CPC H03H 7/38
USPC 333/33

(57) ABSTRACT

Disclosed herein is a variable capacitor module, including a variable capacitor circuit part including a first capacitor unit, a second capacitor unit connected in parallel with the first capacitor unit, and first and second switch units connected between the first and second capacitor units, and selecting at least one capacitor unit according to operations of the first and second switch units, wherein the variable capacitor circuit part is present in plural, and the plural variable capacitor parts are connected in parallel with each other, and thus, an asymmetric phenomenon where the RF terminal has directivity by gate resistance of the switch can be removed.

### CROSS REFERENCE(S) TO RELATED APPLICATIONS

This application claims the benefit under 35 U.S.C. Section 119 of Korean Patent Application Serial No. 10-2012-0044769, entitled “Variable Capacitor Module” filed on Apr. 27, 2012, which is hereby incorporated by reference in its entirety into this application.

### BACKGROUND OF THE INVENTION

1. Technical Field

The present invention relates to a variable capacitor module, and more particularly to a variable capacitor module applicable in a tunable matching network (TMN) of a wireless communication device.

2. Description of the Related Art

Recently, with the rapid development of wireless communication technology, 4 generation (4G) mobile communication represented by long term evolution (LTE) has emerged in addition to current 3 generation (3G) mobile communication, and as functions of the 3G mobile communication network are added to those of the 4G mobile communication network, the number of types that needs to be supported by mobile phones is increasing.

Therefore, in view of current RF functions, various frequency bands need to be covered by using one RF chain, and the power consumed by a power amplifier (PA) needs to be optimized by optimizing front-end matching including an antenna while using a mobile phone.

In order to implement the above function, flexibility is supplemented by adding a tunable matching network circuit to the existing RF front end having a fixed structure, and in order to vary the matched value such as impedance or the like depending on the varied conditions, a variable capacitor module was used in the related art.

FIG. 1 is a schematic diagram of a variable capacitor module according to the related art.

Referring to FIG. 1, a variable capacitor module includes a plurality of capacitor elements C, 2C, 4C, 8C, and 16C connected in parallel between an RF input terminal (RF in) and an RF output terminal (RF out), and switch elements SW1˜SW5 connected in series to the capacitor elements C, 2C, 4C, 8C, and 16C. The switch elements SW1˜SW5 are controlled to be operated, thereby varying desired capacitances (C˜31C). Here, in the variable capacitor module, one of the important figure-of-merits is a quality factor, and this quality factor is largely influenced by a resistance component.

In the tunable matching network circuit, one of an RF+ terminal and an RF− terminal is connected to a signal and the other thereof is connected to a ground, and the quality factor is different for each of the cases. The main reason is that, while the switch element is in an ON operation, an equivalent resistance in the case where the RF+ terminal is connected to the signal is calculated as if it is connected in parallel with resistors connected to a switch element of FIG. 1 and an equivalent resistance in the case where the RF− terminal is connected to the signal is calculated as if it is connected in parallel with capacitor elements.

In configuring the tunable matching network circuit, different characteristics are exhibited depending on directions of the variable capacitor module, and thus, the risk of manufacturing defects is increasing, and additional costs for management thereof occur.

### Related Art Document

U.S. Patent Laid-Open Publication No. 2011/0002080A1

### SUMMARY OF THE INVENTION

An object of the present invention is to provide a variable capacitor module capable of improving a quality factor by employing a structure where a plurality of switch units are connected to each other between a plurality of capacitor units connected in parallel with each other, and implementing uniform characteristics regardless of connection directivity with a tunable matching network.

According to an exemplary embodiment of the present invention, there is provided a variable capacitor module, including, a variable capacitor circuit part including a first capacitor unit, a second capacitor unit connected in parallel with the first capacitor unit, and first and second switch units connected between the first and second capacitor units, and selecting at least one capacitor unit according to operations of the first and second switch units, wherein the variable capacitor circuit part is present in plural, and the plural variable capacitor parts are connected in parallel with each other.

The first switch unit may be connected between first electrodes included in the first and second capacitor units, and the second switch unit may be connected between second electrodes included in the first and second capacitor units.

The first electrodes may be positive (+) electrodes included in the first and second capacitor units; and the second electrodes may be negative (−) electrodes included in the first and second capacitor units.

The first and second capacitor units each may be composed of at least one capacitor.

Here, when the capacitor unit may be composed of two or more capacitors, the capacitors are connected in series with each other.

The first and second switch units each may be composed of at least one switch.

Here, when the switch unit is composed of two or more switches, the switches may be connected in series with each other.

The variable capacitor module may further include: a first RF terminal connected with first electrodes included in the plurality of first capacitor units; and a second RF terminal connected with second electrodes included in the plurality of second capacitor units.

The first and second RF terminals may be used as an RF input terminal and an RF output terminal.

The first and second RF terminals may be electrically insulated from each other.

According to another exemplary embodiment of the present invention, there is provided a variable capacitor module, including: a capacitor circuit part including first to fourth capacitor units connected in parallel with each other; a switching circuit part including first and second switch units connected between first electrodes and between second electrodes included in the first and second capacitor units, respectively, and third and fourth switch units connected between first electrodes and between second electrodes included in the third and fourth capacitor units, respectively, and varying a capacitance of the capacitor circuit part by selecting at least one capacitor unit according to operations of the switch units; a first RF terminal connected with the first electrodes included in the first and third capacitor units; and a second RF terminal connected with the second electrodes included in the second and fourth capacitor units.

The capacitance of the capacitor circuit unit may be a sum of capacitances of the first and second capacitor units when the first and second switch units are ON-operated.

The capacitance of the capacitor circuit unit may be a sum of capacitances of the third and fourth capacitor units when the third and fourth switch units are ON-operated.

The capacitance of the capacitor circuit unit may be a sum of capacitances of the first to fourth capacitor units when the first to fourth switch units are ON-operated.

### BRIEF DESCRIPTION OF THE DRAWINGS

FIG. 1 is a schematic diagram of a variable capacitor module according to the related art.

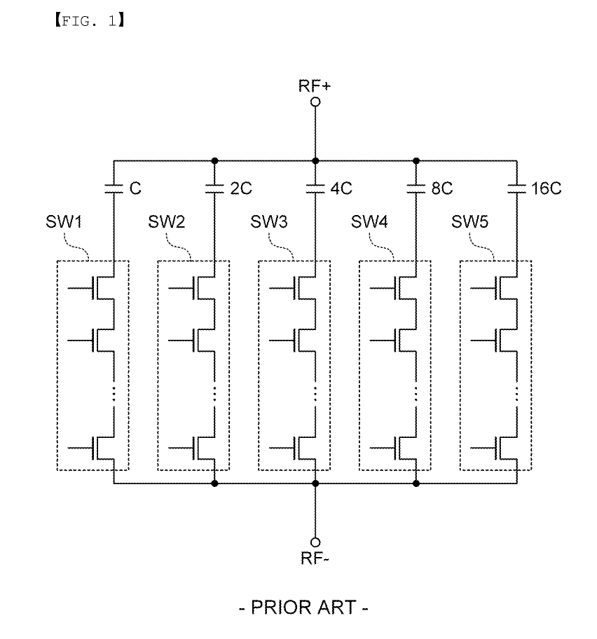

FIG. 2 is a diagram of a wireless communication device according to an exemplary embodiment of the present invention.

FIG. 3 is a detailed diagram of a tunable matching network circuit part.

FIG. 4 is a diagram of a variable capacitor module according to an exemplary embodiment of the present invention.

FIG. 5 is a diagram of a variable capacitor module according to another exemplary embodiment of the present invention.

FIG. 6 shows a case where first to fourth capacitor units each are composed of a plurality of capacitors in FIG. 5.

FIG. 7 shows a case where first to fourth switch units each are composed of a plurality of switches in FIG. 5.

FIG. 8 shows a case where first to fourth capacitor units each are composed of a plurality of capacitors and first to fourth switch units each are composed of a plurality of switches in FIG. 5.

### DESCRIPTION OF THE PREFERRED EMBODIMENTS

Terms and words used in the present specification and claims are not to be construed as a general or dictionary meaning but are to be construed as meaning and concepts meeting the technical ideas of the present invention based on a principle that the inventors can appropriately define the concepts of terms in order to describe their own inventions in best mode.

Therefore, the configurations described in the embodiments and drawings of the present invention are merely most preferable embodiments but do not represent all of the technical spirit of the present invention. Thus, the present invention should be construed as including all the changes, equivalents, and substitutions included in the spirit and scope of the present invention at the time of filing this application.

Hereinafter, embodiments of the present invention will be described with reference to the accompanying drawings.

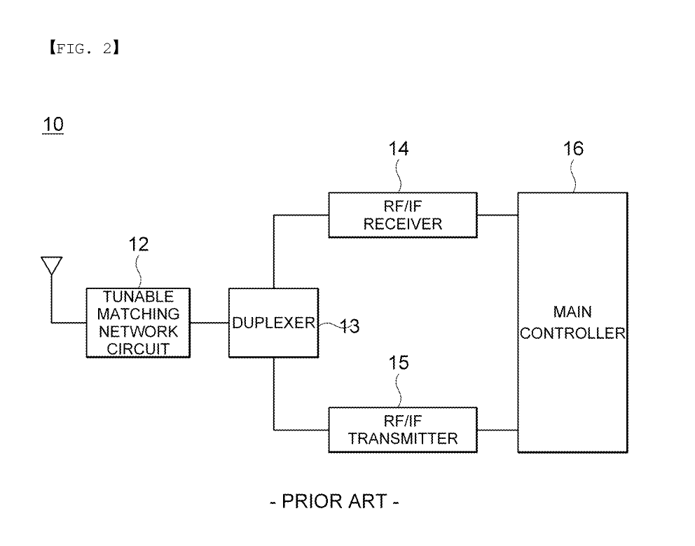

FIG. 2 is a diagram of a wireless communication device according to an exemplary embodiment of the present invention.

As shown in FIG. 2, a wireless communication device 10 includes a tunable matching network circuit part 12, a duplex 13, an RF/IF receiver 14, an RF/IF transmitter 15, and a main controller 16.

The tunable matching network circuit part 12 may be composed of inductors, capacitors, and the like. The tunable matching network circuit 12 may change a capacitance by using a variable capacitor module, to thereby have a variable impedance value, and may change the entire impedance value. The tunable matching network may perform antenna matching by changing the entire impedance value according to the used environment.

The duplexer 13 serves to separate transmission and reception signals at an antenna. The RF/IF receiver 14 converts a signal received through the duplexer 13 into a baseband signal to transfer the signal to the main controller 16, and includes a low noise amplifier, a band pass filter, a power amplifier, and the like, for lowering a noise figure of the received signal.

The RF/IF transmitter 15 converts the baseband signal generated in the main controller 16 into a signal transmittable through a mobile communication network, and includes a power amplifier, a band pass filter, and the like.

The main controller 16 controls the entire operations of the wireless communication device, and outputs a control signal for antenna matching.

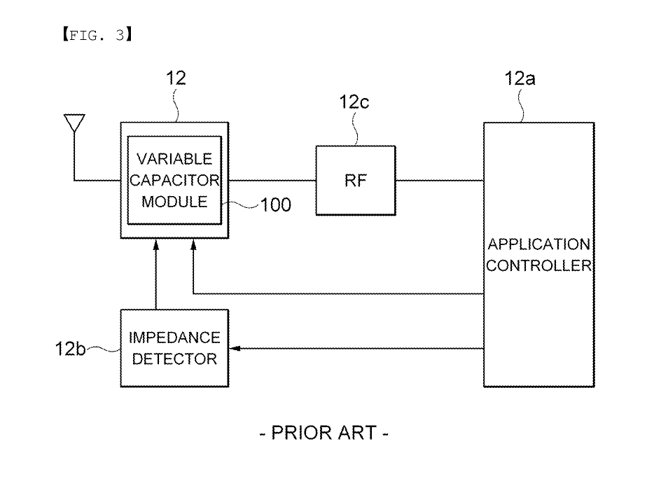

FIG. 3 is a detailed diagram of the tunable matching network circuit part. Referring to FIG. 3, the tunable matching network circuit part 12 varies a capacitance in order to improve power transfer efficiency from the power amplifier to the antenna, and may include a variable capacitor module 100, an application controller 12a, and an impedance detector 12b.

Here, the tunable matching network circuit part 12 may adjust the capacitance by using an open loop manner and a closed loop manner. According to the open loop manner, the capacitance is adjusted by the application controller 12a with reference to a previously stored look-up table. According to the closed loop manner, the capacitance is adjusted depending on the conditions based on the signal detected by the impedance detector 12b.

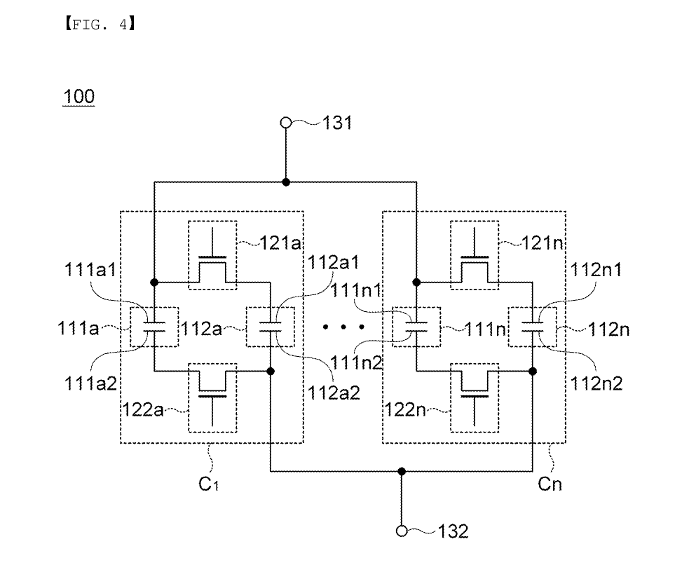

FIG. 4 is a diagram of the variable capacitor module according to an exemplary embodiment of the present invention.

As shown in FIG. 4, a variable capacitor module 100 may include a plurality of variable capacitor circuit parts C₁˜C₁.

Here, the variable capacitor circuit part C₁ may include a first capacitor unit 111a, a second capacitor unit 112a connected in parallel with the first capacitor unit 111a, and first and second switch units 121a and 122a connected between the first and second capacitor units 111a and 112a, and may vary the entire capacitance by selecting at least one capacitor unit according to operations of the first and second switch units 121a and 122a.

The first and second capacitor units 111a˜111n and 112a˜112n may be present in plural, and may be connected in parallel with each other, respectively. In addition, the first and second capacitor units 111a˜111n and 112a˜112n each may be composed of at least one capacitor.

The first and second switch units 121a˜121n and 122a˜122n may be present in plural, and may be connected between electrodes included in the first and second capacitor units 111a˜111n and 112a˜112n. More specifically, the first switch unit 121a may be connected between first electrodes 111a1 and 112a1 included in the first and second capacitor units 111a and 112a, and the second switch unit 122a may be connected between second electrodes 111a2 and 112a2 included in the first and second capacitor units 111a and 112a. The first and second switch units 121a˜121n and 122a˜122n each may be composed of at least one switch.

In addition, the variable capacitor module 100 according to an exemplary embodiment of the present invention may further include a first RF terminal 131 connected with the first electrodes 111a1˜111n1 included in the plurality of first capacitor units 111a˜111n, and a second RF terminal 132 connected with the second electrodes 112a2˜112n2 included in the plurality of second capacitor units 112a˜112n.

Here, the first and second RF terminals 131 and 132 may be used as an RF input terminal and an RF output terminal, respectively, and the first and second RF terminals 131 and 132 may be electrically insulated from each other.

By employing this structure, the entire capacitance can be changed through the effect of increasing or decreasing the areas of the electrodes included in the first and second capacitors according to ON/OFF operations of the first and second switch units. Here, the first electrode may be a positive (+) electrode included in the capacitor unit and the second electrode may be a negative (−) electrode included in the capacitor unit.

In the first variable capacitor circuit part C₁, if the first capacitor unit has a capacitance of C1 and the second capacitor unit has a capacitance of C2, the entire capacitance may be C1+C2 when all the first and second switch units are in an ON operation.

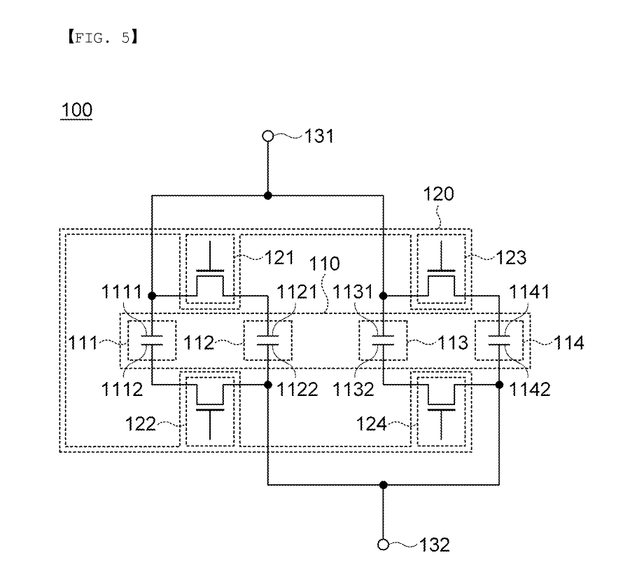

FIG. 5 is a diagram of a variable capacitor module according to another exemplary embodiment of the present invention.

As shown in FIG. 5, a variable capacitor module 100 may include a capacitor circuit part 110, a switching circuit part 120, and first and second RF terminals 131 and 132.

Here, the capacitor circuit part 110 may include first to fourth capacitor units 111˜114 connected in parallel with each other.

The switching circuit unit 120 may include first and second switch units 121 and 122 connected between the first electrodes 1111 and 1121 and between the second electrodes 1112 and 1122 included in the first and second capacitor units 111 and 112, respectively, and third and fourth switch units 123 and 124 connected between the first electrodes 1131 and 1141 and between the second electrodes 1132 and 1142 included in the third and fourth capacitor units 113 and 114, respectively. The switching circuit unit 120 may vary the capacitance of the capacitor circuit part 110 by selecting at least one capacitor unit according to operations of the switch units.

A first RF terminal 131 may be connected with the first electrodes 1111 and 1131 included in the first and third capacitor units 111 and 1143, and connected with the second electrodes 1122 and 1142 included in the second and fourth capacitor units 112 and 114.

The capacitance of the capacitor circuit part, which is varied according to operations of the switch units, will be described more specifically. If the first and second switch units 121 and 122 are ON-operated, the capacitance of the capacitor circuit part 110 may be the sum of capacitances of the first and second capacitor units 111 and 112.

In addition, if the third and fourth switch units 123 and 124 are ON-operated, the capacitance of the capacitor circuit part 110 may be the sum of capacitances of the third and fourth capacitor units 113 and 114.

Moreover, if the first to fourth switch units 121, 122, 123, and 124 are ON-operated, the capacitance of the capacitor circuit part 110 may be the sum of capacitances of the first to fourth capacitor units 111, 112, 113, and 114.

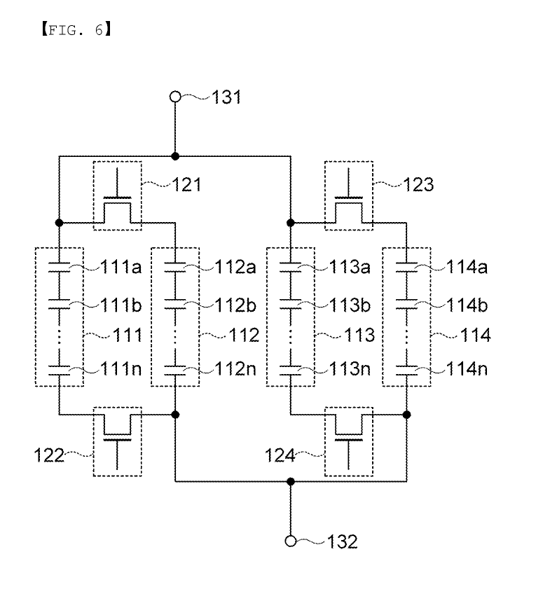

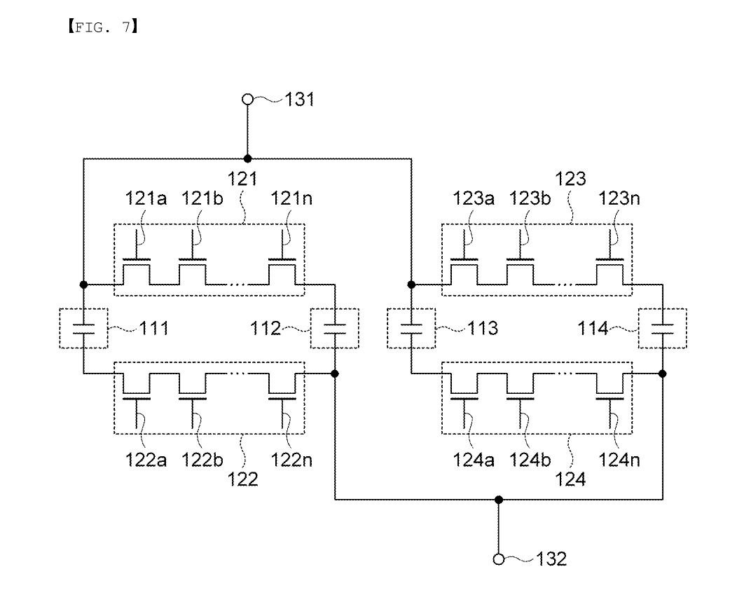

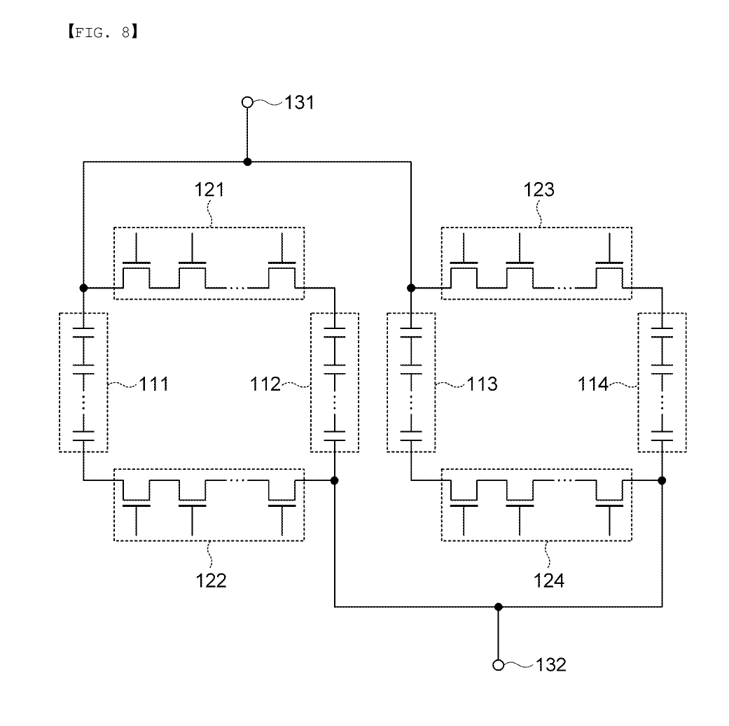

FIG. 6 shows a case where the first to fourth capacitor units each are composed of a plurality of capacitors in FIG. 5; FIG. 7 shows a case where the first to fourth switch units each are composed of a plurality of switches in FIG. 5; FIG. 8 shows a case where the first to fourth capacitor units each are composed of a plurality of capacitors and the first to fourth switch units each are composed of a plurality of switches in FIG. 5.

As shown in FIG. 6, first and second capacitor units 111 and 112 are composed of one or more capacitors 111a˜111n and 112a˜112n connected in series with each other, respectively, and third and fourth capacitor units 113 and 114 are composed of one or more capacitors 113a˜113n and 114a˜114n connected in series with each other, respectively. As shown in FIG. 7, first and second switch units 121 and 122 are composed of one or more capacitors 121a˜121n and 122a˜122n connected in series with each other, respectively, and third and fourth switch units 123 and 124 are composed of one or more capacitors 123a˜123n and 124a˜124n connected in series with each other, respectively. This is for distributing the voltage in order to bear high RF power (power handling) of a wireless communication device.

In addition, as shown in FIG. 8, the first to fourth capacitor units 111˜114 may have one or more capacitors 111a˜111n, 112a˜112n, 113a˜113n, and 114a˜114n connected in series with each other, respectively, and the first to fourth switch units 121˜124 may have one or more switches 121a˜121n, 122a˜122n, 123a˜123n, and 124a˜124n connected in series with each other, respectively.

As set forth above, according to the variable capacitor module according to an exemplary embodiment of the present invention, an asymmetric phenomenon where the RF terminal has directivity by gate resistance of the switch can be removed by employing a structure where the plurality of switch units are respectively connected between the electrodes included in the plurality of capacitor units connected in parallel with each other.

The present invention has been described in connection with what is presently considered to be practical exemplary embodiments. Although the exemplary embodiments of the present invention have been described, the present invention may be also used in various other combinations, modifications and environments In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A variable capacitor module, comprising,
a variable capacitor circuit part including a first capacitor unit, a second capacitor unit connected in parallel with the first capacitor unit, and first and second switch units connected between the first and second capacitor units, and selecting at least one capacitor unit according to operations of the first and second switch units,
wherein the variable capacitor circuit part is present in plural, and the plural variable capacitor parts are connected in parallel with each other.

2. The variable capacitor module according to claim 1, wherein the first switch unit is connected between first electrodes included in the first and second capacitor units, and the second switch unit is connected between second electrodes included in the first and second capacitor units.

3. The variable capacitor module according to claim 2, wherein the first electrodes are positive (+) electrodes included in the first and second capacitor units; and the second electrodes are negative (−) electrodes included in the first and second capacitor units.

4. The variable capacitor module according to claim 1, wherein the first and second capacitor units each are composed of at least one capacitor.

5. The variable capacitor module according to claim 4, wherein, when the capacitor unit is composed of two or more capacitors, the capacitors are connected in series with each other.

6. The variable capacitor module according to claim 1, wherein the first and second switch units each are composed of at least one switch.

7. The variable capacitor module according to claim 6, wherein, when the switch unit is composed of two or more switches, the switches are connected in series with each other.

8. The variable capacitor module according to claim 1, further comprising:
a first RF terminal connected with first electrodes included in the plurality of first capacitor units; and
a second RF terminal connected with second electrodes included in the plurality of second capacitor units.

9. The variable capacitor module according to claim 8, wherein the first and second RF terminals are used as an RF input terminal and an RF output terminal.

10. The variable capacitor module according to claim 8, wherein the first and second RF terminals are electrically insulated from each other.

11. A variable capacitor module, comprising:
a capacitor circuit part including first to fourth capacitor units connected in parallel with each other;
a switching circuit part including first and second switch units connected between first electrodes and between second electrodes included in the first and second capacitor units, respectively, and third and fourth switch units connected between first electrodes and between second electrodes included in the third and fourth capacitor units, respectively, and varying a capacitance of the capacitor circuit part by selecting at least one capacitor unit according to operations of the switch units;
a first RF terminal connected with the first electrodes included in the first and third capacitor units; and
a second RF terminal connected with the second electrodes included in the second and fourth capacitor units.

12. The variable capacitor module according to claim 11, wherein the capacitance of the capacitor circuit unit is a sum of capacitances of the first and second capacitor units when the first and second switch units are ON-operated.

13. The variable capacitor module according to claim 11, wherein the capacitance of the capacitor circuit unit is a sum of capacitances of the third and fourth capacitor units when the third and fourth switch units are ON-operated.

14. The variable capacitor module according to claim 11, wherein the capacitance of the capacitor circuit unit is a sum of capacitances of the first to fourth capacitor units when the first to fourth switch units are ON-operated.
